(19) United States
(12) Patent Application Publication
(10) Pub. No.: US 2004/0161925 A1
(43) Pub. Date: Aug. 19, 2004

(54) Method of manufacturing master disc

(76) Inventor: Hiroyuki Yoshimura, Tokyo (JP)

Correspondence Address: ROSSI & ASSOCIATES, P.O. Box 826, Ashburn, VA, 20146-0826, US

(21) Appl. No.: 10/658,599

(22) Filed: Sep. 9, 2003

(30) Foreign Application Priority Data
Feb. 14, 2003 (JP) 2003-037306

(51) Int. Cl. H01L 21/4763

(52) U.S. Cl. 438/637

(57) ABSTRACT

A master disc has improved film thickness distribution of a soft magnetic film embedded in the grooves formed in a silicon substrate thereof. A SiO₂ film is formed on the Si substrate, and the SiO₂ film is patterned and etched to form a mask for forming the grooves (magnetic pattern) on the surface of the substrate. After etching the substrate to form the grooves, a soft magnetic film is embedded in the grooves. Thereafter, the patterned SiO₂ film is removed together with the soft magnetic film not embedded in the grooves. The soft magnetic film can be formed of cobalt or an alloy of iron and cobalt or alloy of iron, cobalt, and nickel.

### BACKGROUND

In a hard disc drive (HDD), data are recorded/reproduced while a magnetic head is floated above the surface of a rotating magnetic recording medium at a gap of several tens nm by a floating mechanism (slider). Bit information on the magnetic recording information is stored in data tracks arranged concentrically on the medium, and the data recording/reproducing head is moved/positioned to a target data track on the surface of the medium at a high speed to perform the data recording/reproduction.

A positioning signal (servo signal) for detecting the relative position between the head and each data track is concentrically written on the surface of the magnetic recording medium, and the head carrying out the data recording/reproduction detects the position thereof at a fixed time interval. The magnetic recording mediums is installed in the HDD device so that the center of the writing signal of the servo signal does not deviate from the center of the medium (or the center of the locus of the head), and then the servo signal is written by using a dedicated device (servo writer).

The recording density of the present HDDs has reached 100 Gbits/in², and the storage capacity thereof is increasing 60% per year. In connection with this, there is a tendency for the density of the servo signal with which the head detects the position thereof to increase, as well as to increase the writing time of the servo signal year by year. The increase of the writing time of the servo signal is one factor that reduces productivity of HDD and increases the cost thereof.

In comparison to the servo signal writing system using the signal writing head of the servo writer described above, collectively writing a servo signal through a magnetic transfer technique can dramatically shorten the writing time of servo information. FIGS. 6A-6C, 7A, and 7B illustrate this magnetic transfer technique.

FIG. 7A shows a cross-sectional view of a magnetic recording medium with a permanent magnet moving on the surface thereof while keeping the magnet spaced at a fixed interval (1 mm or less). The magnetic film of the medium is initially not magnetized in a uniform direction, but is magnetized in a uniform direction by the magnetic field leaking from the gap of the permanent magnet (arrows in the magnetic film in FIGS. 7A and 7B represent the direction of the magnetization). This step is referred to as an initial demagnetizing step.

The arrow illustrated in FIG. 6A represents a movement path of the permanent magnet, where the magnetic layer is uniformly magnetized in the circumferential direction. FIG. 6B shows the state where a magnetic transfer master disc (hereinafter master disc) is arranged above the magnetic recording medium. FIG. 6C shows the state where magnetic transfer is carried out by bringing the master disc into close contact with the surface of the magnetic recording medium while moving the permanent magnet for magnetic transfer along the movement path (indicated by an arrow).

FIG. 7B shows the magnetic transfer technique. Here, the master disc has a soft magnetic film (Co type soft magnetic film) embedded at a surface side, which is brought into contact with the medium surface of the silicon substrate. When the silicon substrate (master disc) having a pattern of the soft magnetic film embedded therein is interposed between the permanent magnet and the magnetic recording medium as shown in FIG. 7B, the magnetic field leaking from the permanent magnet and infiltrating into the silicon substrate (the direction of magnetic field for transfer signal writing is opposite to the direction of magnetic field for demagnetization) can be transmitted through the silicon substrate to magnetize the magnetic layer at the portions where the soft magnetic material is missing. However, at the portions where the pattern of the soft magnetic layer exists, the magnetic field is transmitted through the soft magnetic film to form a magnetic path having small magnetic resistance. Therefore, at the positions where the soft magnetic layer exists, the magnetic field leaking from the silicon substrate is reduced, and new magnetization writing is not carried out. According to the above mechanism, the servo signal can be magnetically transferred.

FIGS. 8A-8E show the process of manufacturing the current master disc, as disclosed for example in JP-A-2001-126247. A photoresist or resist film (1.2 μm thick) is coated on the surface of a silicon substrate (500 μm thick) by using a spin coater (FIG. 8A), and then the resist film is patterned using photolithography as in the case of a normal silicon-semiconductor manufacturing method (FIG. 8B). The resist film is used as a mask for etching the substrate. The resist film is formed of novolak-based material, and thus is not resistant to etching. Therefore, it is important that the resist film be thick to the extent that it does not become extinguished by the etching step.

Next, the silicon substrate is dry-etched 500 nm by using a reactive plasma etching method (reactive gas: methane trichloride) to form grooves (FIG. 8C). Thereafter, a cobalt (Co) based soft magnetic film (500 nm thick or otherwise needed to fill the grooves) is formed by sputtering over the remaining resist film (FIG. 8D). The soft magnetic film becomes embedded in the grooves. After the soft magnetic film is formed, the silicon substrate is immersed in a solvent to dissolve and remove the resist film (while using ultrasonic wave or the like as occasion demands) remaining between the soft magnetic film and the silicon substrate (FIG. 8E).

Furthermore, JP-A-2001-102446 discloses that a metal pattern can be used to make a finer pattern. Moreover, JP-A-2002-237022 discloses that the larger the saturated magnetic flux density of a recording medium is, the more preferable it is. Moreover, JP-A-2001-155336 discloses the composition of a recording layer.

FIGS. 9A-9G show cross-sectional shapes (micrographs) of the etched grooves having different groove widths when the soft magnetic film is embedded in the etched grooves according to the conventional process described above. The groove widths illustrated among FIGS. 9A-9G respectively are 0.5 μm, 1.0 μm, 1.5 μm, 2.0 μm, 2.5 μm, 3.0 μm, and 3.5 μm. These figures each illustrate a resist film 1.2 μm thick and a soft magnetic film 0.5 μm thick formed in this order on a silicon substrate.

Sputtered particles having poor rectilinear propagation performance adhere to the side walls of the photoresist, and growth of these sputtered particles can disturb the propagation of sputtered particles having excellent rectilinear propagation performance. Therefore, the film forming rate is lowered at both the ends of each groove, resulting in a thickness distribution. FIG. 10 shows the relationship between the groove width and the fill thickness at the groove portions. In FIG. 10, the film thickness of the soft magnetic film at the center of the bottom surface, the left end of the bottom surface, the right end of the bottom surface, the left end of the side surface, and the right end of the side surface are shown in this order from the upper curved line at the groove width of 2.5 μm on the abscissa axis. As the groove width is reduced, the thickness distribution of the film deposited in the grooves is much more remarkable, and at the groove width of 1.0 μm or less, it is remarkable to the extent that it is not negligible.

When the film thickness distribution is remarkable as described above and thus a thinner portion is formed, the soft magnetic film falls into a magnetically saturated state at that portion, and the external magnetic field leaks to portions other than the soft magnetic film, so that the width of the transferred magnetized pattern becomes narrower than a desired value (an ideal state illustrated in FIGS. 12A-12E under which no film thickness distribution occurs), as shown in FIGS. 11A-11E. In the worst case scenario, the magnetization reversal can occur even beneath the soft magnetic film, resulting in missing pits. Therefore, even when the groove width is not more than 1.0 μm, the film thickness distribution of the soft magnetic film embedded in the groove portions needs to be reduced as much as possible. FIGS. 13A-13E show the magnetization state when no soft magnetic film is provided.

For the magnetic transfer technique to work, the magnetic field needs to be no more than Hc under which most of the magnetic field created by the permanent magnet passes through the soft magnetic film embedded in the master disc and the magnetic field applied to the magnetic layer of the magnetic recording medium brought into close contact with the master disc can induce reversal of magnetization as shown in FIG. 7B. If the soft magnetic film becomes magnetically saturated, the magnetic field would leak to the magnetic layer of the magnetic recording medium, and in the worst case scenario, the magnetic field can be intensified to Hc or more at which magnetization reversal occurs so that magnetic pulses are formed at unexpected positions. Accordingly, the soft magnetic film should be formed of a material having high saturated magnetic flux density and having a sufficient thickness. Therefore, current master discs are manufactured using cobalt as the material of the soft magnetic layer, while setting the thickness of the soft magnetic layer to 0.5 μm.

FIGS. 14A and 14B show the intensities of the surface magnetic field Ha, Hb, Hg of the magnetic recording layer when the thickness T of the soft magnetic film is varied in FIG. 15, and a line of Ha in FIGS. 14A, 14B represents the intensity of the surface magnetic field with respect to the recording magnetic field Hex under the soft magnetic film. It is shown that under the same condition of the recording magnetic field Hex, leakage occurs in the soft magnetic film having a smaller thickness T even when the recording magnetic field Hex is low. As described above, the following problems exist in connection with embedding the soft magnetic film in the grooves having sub-micron widths.

First, the thickness of the soft magnetic film needs to be reduced, the adhesion amount of sputtered particles to the side walls of the grooves needs to be reduced, and the film thickness distribution of the soft magnetic film embedded in the grooves needs to be reduced. Second, the magnetic flux density per unit area needs to be not more than the saturated magnetic density of the soft magnetic film so that no magnetic saturation occurs even when recording magnetic field is applied.

Accordingly, there is a need for a master disc for magnetic transfer that can solve the above problems. The present invention addresses this need.

### SUMMARY OF THE INVENTION

The present invention relates to a method of manufacturing a master disc for transferring a magnetic pattern to a magnetic recording medium and a master disc thereof.

One aspect of the present invention is a method of manufacturing a master disc for transferring a magnetic pattern to a magnetic recording medium. The method includes providing a substrate, forming an SiO₂ film on the surface of the substrate, forming a pattern on the Si0₂ film corresponding to a predetermined magnetic pattern, etching the substrate using the patterned Si0₂ film as a mask to form grooves corresponding to the predetermined magnetic pattern, embedding a soft magnetic film in the grooves, and removing the patterned Si0₂ film.

The substrate can be a silicon substrate and the soft magnetic film can be formed of cobalt, or an alloy of iron (Fe) and cobalt (Co) or an alloy of iron, cobalt, and nickel (Ni). The composition of the alloy can be set to satisfy an atomic ratio of Fe: 52 to 72%, Co: 28 to 48%, and Ni: 0 to 3%. The Si0₂ film can have a thickness of 0.2 μm formed on the surface of the substrate by thermal oxidation. The depth of the grooves in the substrate can be 0.5 μm or 0.25 μm.

The pattern forming step can include the steps of forming a photoresist film on the Si0₂ film, patterning the photoresist film corresponding to the predetermined magnetic pattern, developing the photoresist film to form a photoresist mask for etching the SiO₂ film, and etching the SiO₂ to form the pattern of SiO₂ film corresponding to the predetermined magnetic pattern, and further including the step of removing the patterned photoresist film before etching the substrate.

Another aspect of the present invention is a master disc formed according to the above described method.

Another aspect of the present invention is a master disc for transferring a magnetic pattern to a magnetic recording medium. The master disc includes a silicon substrate having grooves corresponding to a magnetic pattern, and a magnetic material filling the grooves. The magnetic material can be formed of an alloy of iron and cobalt or an alloy of iron, cobalt, and nickel. The composition of the alloy satisfies an atomic ratio of Fe: 52 to 72%, Co: 28 to 48%, and Ni: 0 to 3%. The grooves can be 0.25 μm deep.

### BRIEF DESCRIPTION OF THE DRAWINGS

FIGS. 1A-1I illustrate a manufacturing method of a master disc using SiO₂ film according to the present invention.

FIG. 2 is a graphic chart illustrating the saturated magnetic flux density based on the atomic ratio of Co, Fe, Ni alloy.

FIG. 3 is a diagram showing a mode used to calculate the magnetic flux passing through soft magnetic film.

FIGS. 4A and 4B are cross-sectional views showing the sectional shape before the soft magnetic film is embedded in the case of a resist mask.

FIGS. 5A and 5B are cross-sectional views showing the sectional shape before the soft magnetic film is embedded in the case of an SiO₂ mask.

FIGS. 6A-6C are diagrams schematically showing a magnetic transfer process for a magnetic recording medium.

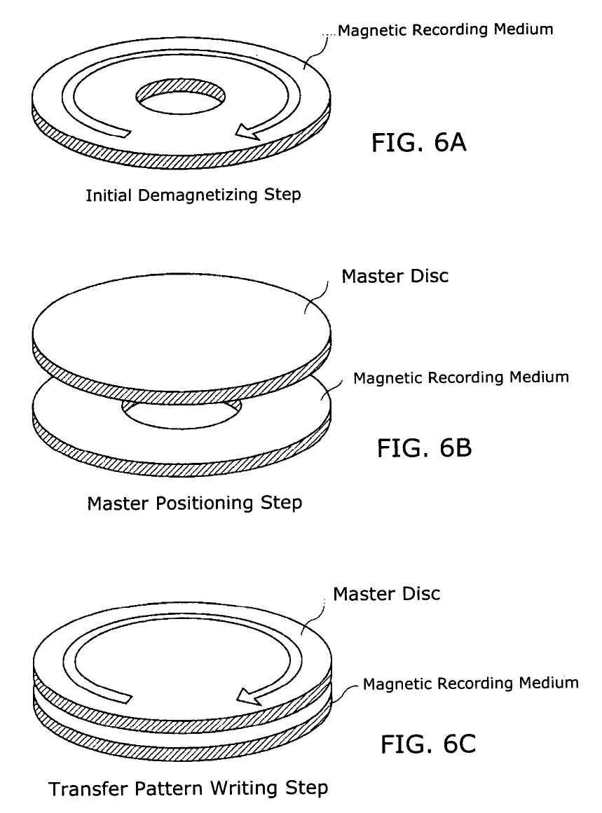

FIGS. 7A and 7B are diagrams showing the principle of magnetic transfer for the magnetic recording medium.

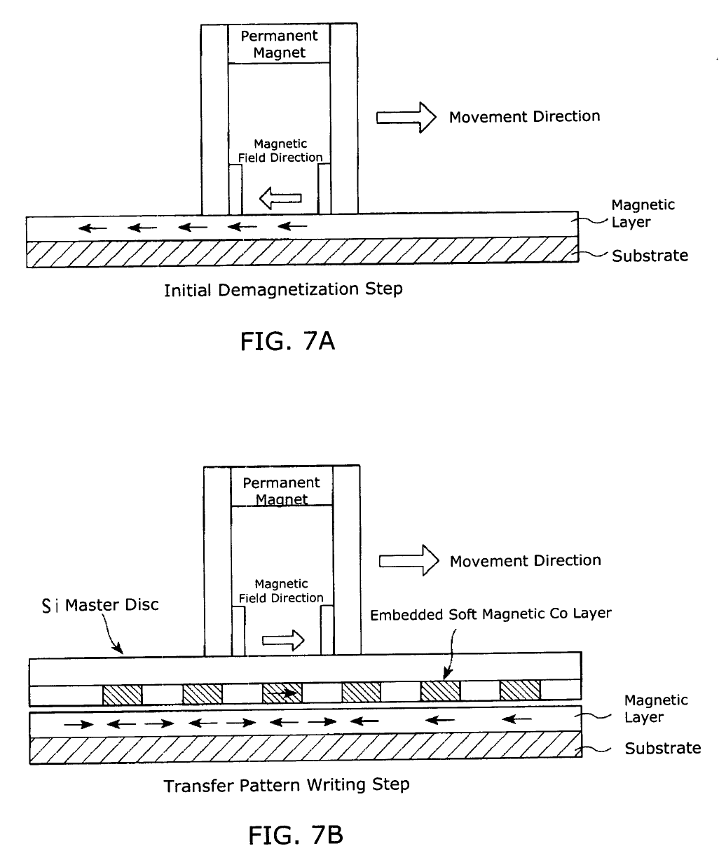

FIGS. 8A-8E illustrate a conventional manufacturing process for the master disc.

FIGS. 9A-9G are cross-sectional views of the soft magnetic film embedded in the etched grooves according to the conventional manufacturing process.

FIG. 10 is a characteristic diagram showing the groove-width dependence of a film thickness distribution.

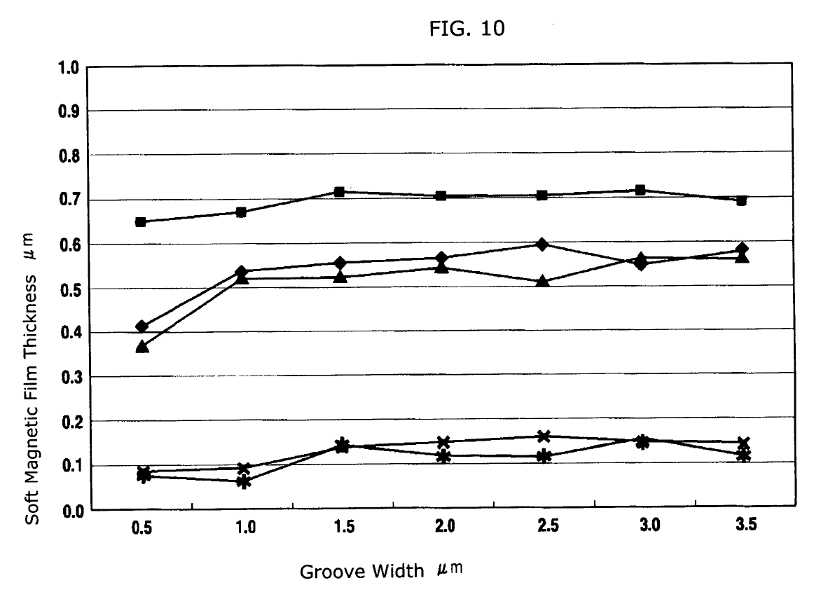

FIGS. 11A-11E are diagrams showing an effect of the film thickness distribution of the soft magnetic film on the magnetic transfer.

FIGS. 12A-12E are diagrams showing an ideal film thickness distribution of the soft magnetic film on the magnetic transfer.

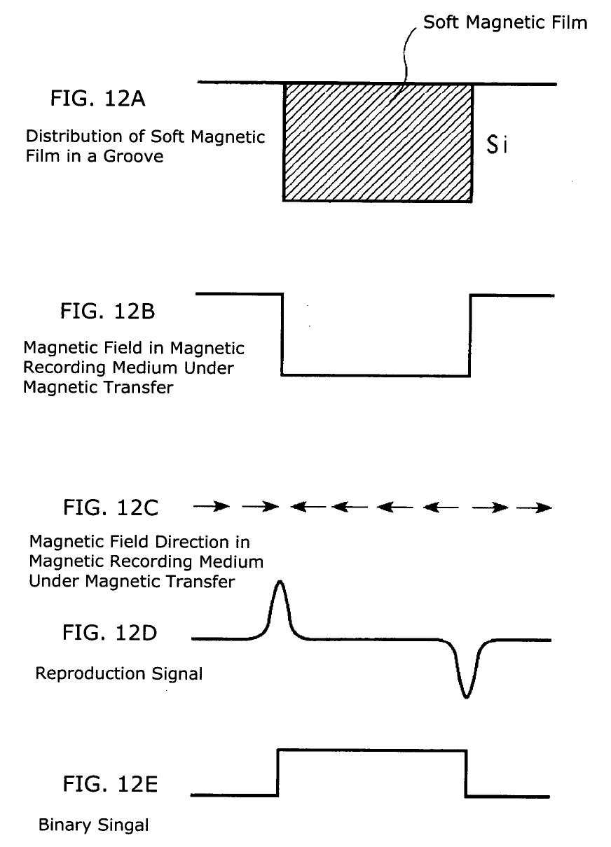

FIGS. 13A-13E are diagrams showing another effect of the film thickness distribution of the soft magnetic film on the magnetic transfer.

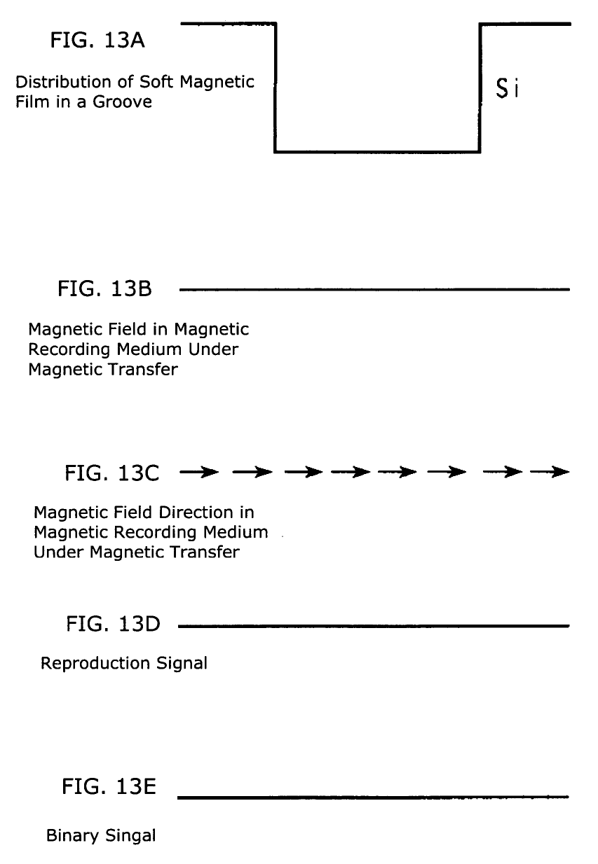

FIGS. 14A and 14B are characteristic diagrams showing the magnetic field intensity on the surface of the magnetic recording medium when the thickness of the soft magnetic layer is varied.

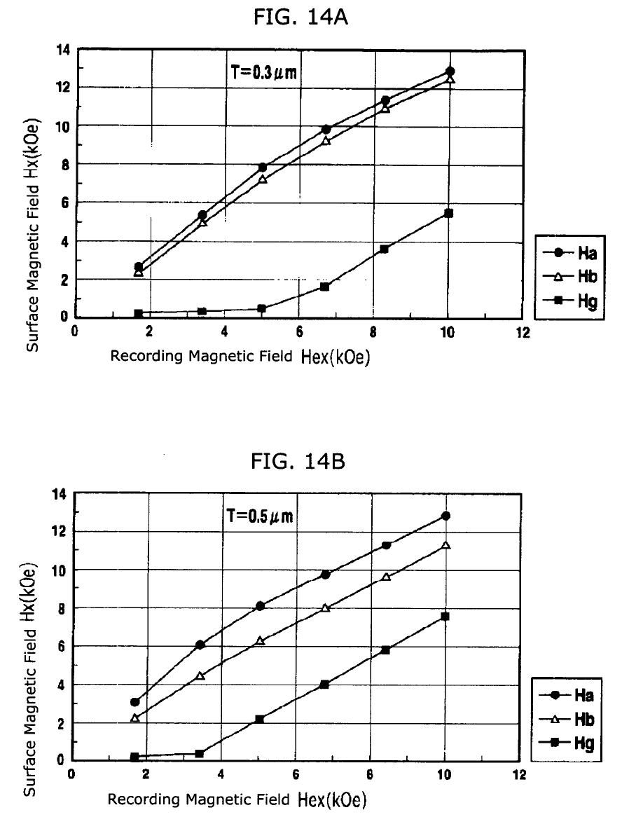

FIG. 15 is a diagram showing the difference in magnetic field intensity on the surface of the magnetic recording medium when the thickness of the soft magnetic layer is varied.

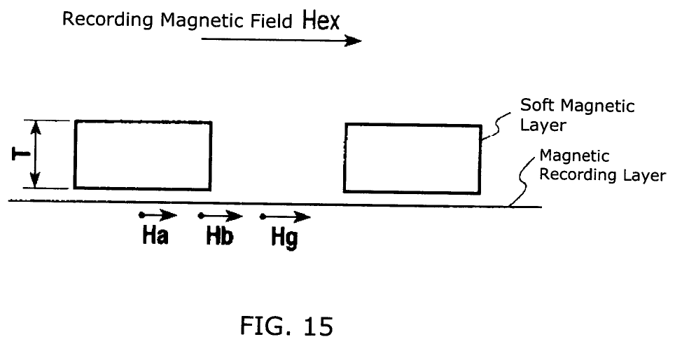

### DETAILED DESCRIPTION

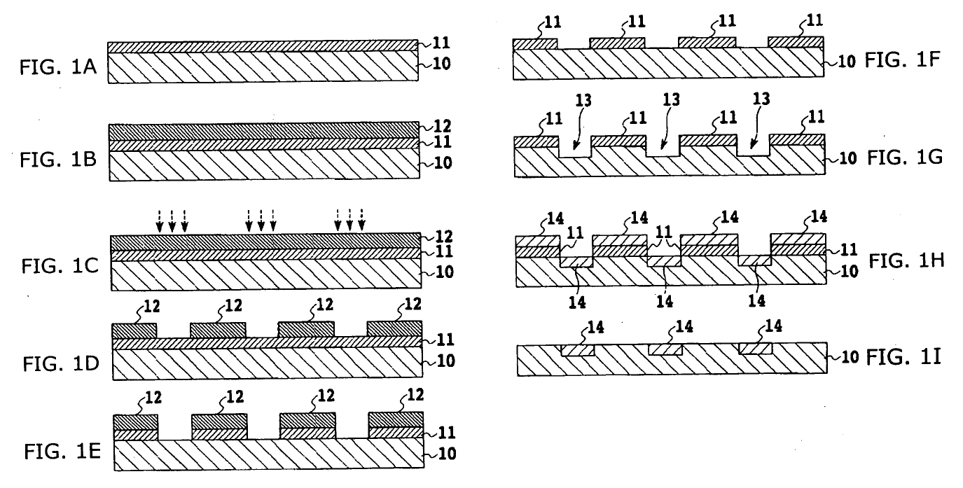

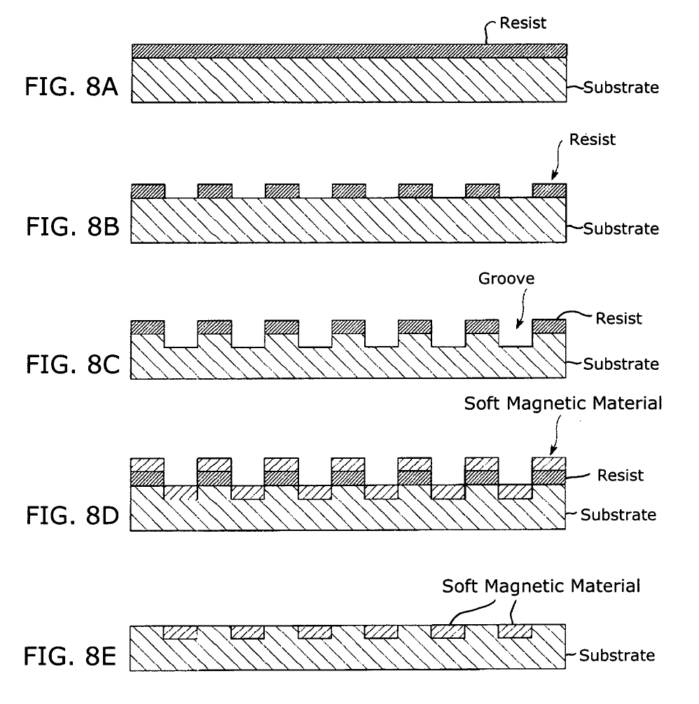

FIGS. 1A-1I illustrate a method of manufacturing a master disc according to the present invention. The present method differs from the conventional method illustrated in FIGS. 8A-8E in that the present method uses a mask of SiO₂ film to form the grooves in the Si substrate by etching. The Si0₂ film is used as the etching mask to form the grooves because the etching rate is significantly lower for SiO₂ and Si (1:20), than that for the resist and Si (1:3). Thus, the thickness of the mask needed to form the grooves having the same depth in the Si substrate by etching can be significantly thinner, 0.2 μm, as opposed to 1.2 μm for the resist mask.

Referring to FIGS. 1A-1I, on a silicon substrate 10, an SiO₂ film 11 0.2 μm thick is formed by thermally oxidizing the surface of the silicon substrate 10 (FIG. 1A). Thereafter, a photoresist film 12 0.2 μm thick can be coated on the SiO₂ film 11 on the surface of the silicon substrate 10 (FIG. 1B). The etching rate of an oxide film etching device can be set to satisfy photoresist:SiO₂=1:2. Thus, the photoresist film of about 0.2 μm thick is sufficient to etch the SiO₂ film 11 0.2 μm thick. After forming the photoresist film 12, it is patterned corresponding to the desired magnetic pattern, for example, by an electron beam exposure device, so that the resist film 12 is exposed to light (FIG. 1C). The photoresist film 12 is developed, for instance, by immersing the substrate in a developing solution to remove the light-exposed portion of the photoresist film 12 (FIG. 1D). This exposes the SiO₂ film 11 at the areas corresponding to the magnetic pattern.

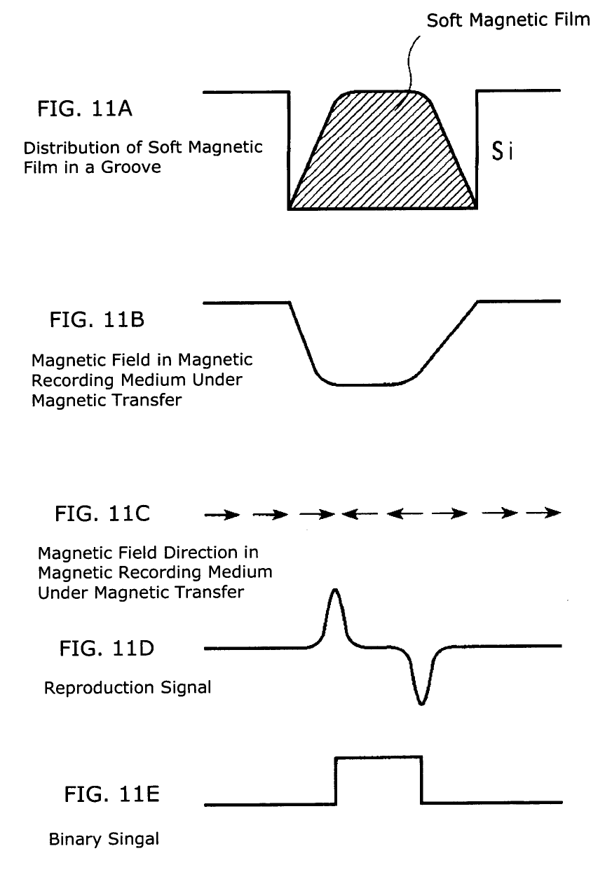

Using the developed photoresist film 12 as a mask, the exposed SiO₂ film 11 can be etched with an oxide film etcher, until the surface of the silicon substrate 10 appears or becomes exposed, so that the pattern formed on the photoresist film 12 is transferred to the Si0₂ film 11 (FIG. 1E). Since the photoresist film 12 is unnecessary, it can be removed by heating (ashed) so that only the unetched portions of the SiO₂ film are left (forming a mask of the SiO₂ film 11) on the substrate (FIG. 1F). Using the remaining portion of the SiO₂ film as a mask, the exposed surface of the silicon substrate is etched with an Si etching device, to form grooves 13 each having a predetermined depth (0.5 μm or 0.25 μm) (FIG. 1G). A soft magnetic film 14 can be deposited on the substrate 10 by sputtering, for instance, with a sputtering device having excellent rectilinear propagation performance to embed the soft magnetic film 14 in the grooves 13 (FIG. 1H). The soft magnetic film 14 can be formed of cobalt (Co) or an alloy of cobalt (described in detail below). After depositing the soft magnetic film, the remaining Si0₂ film 11 is removed, such as by peeling off from the boundary between the Si0₂ film 11 and the silicon substrate 10 by using hydrofluoric acid to remove the Si0₂ film 11 together with unnecessary soft magnetic film 14. Now the master disc is left with only the soft magnetic film 14 embedded in the grooves 13 of the silicon substrate 10 (FIG. 11).

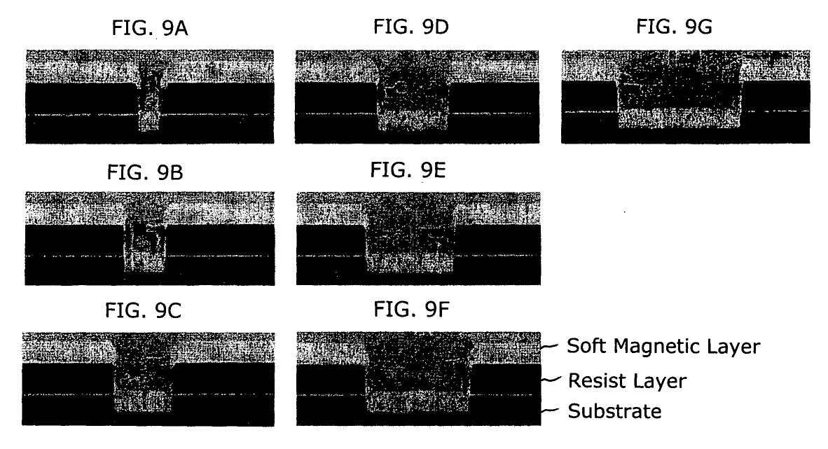

As previously explained with respect to FIGS. 9A-9G, as the groove width is varied, sputtered particles having poor rectilinear propagation performance adhere to the side walls of the photoresist at the small-width portions of the grooves, and the growth of these sputtered particles reduces the film forming rate at both the ends of the grooves, so that a film thickness distribution occurs. The mask thickness, when the photoresist is used as a mask for forming the grooves, is equal to 1.2 μm as previously described. According to the present invention, however, the mask thickness can be reduced to 0.2 μm because the mask for forming the grooves is made of an Si0₂ film 11, so that the adhesion area to the side surface can be reduced, and the reduction of the film forming rate at both the ends of each groove portion can be suppressed.

According to a the present invention, the grooves 13 can set to 0.25 μm (as opposed to 0.50 μm) by using a soft magnetic film made of an alloy of iron (Fe), cobalt (Co), and nickel (Ni) rather than pure or near pure cobalt. The alloy material can have a composition of Fe: 52 to 72%, Ni: 0 to 3% and Co: 28 to 48% in atomic ratio.

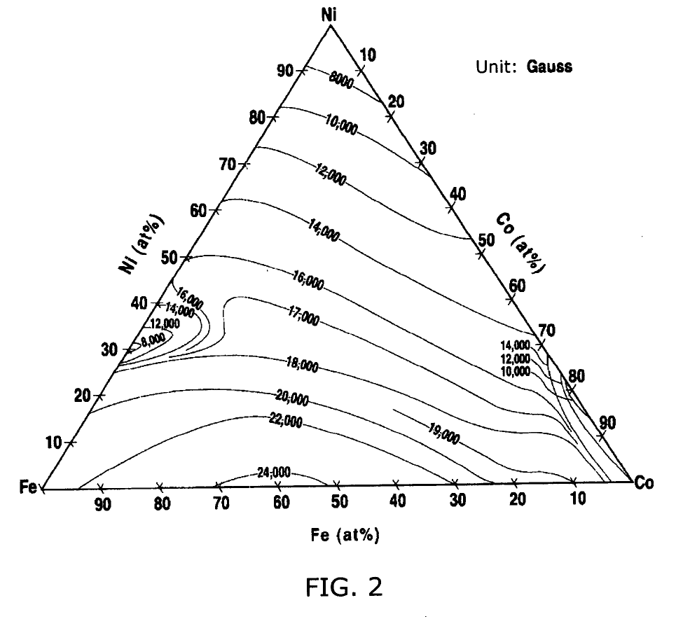

FIG. 2 is a graphic chart showing the saturated magnetic flux density (in gauss) based on the atomic ratio with respect to the alloy of Co, Fe, and Ni. From FIG. 2, it is shown that the saturated magnetic flux density of Co is equal to about 12,000 gauss, and the saturated magnetic flux density of the alloy having the composition of Fe:52 to 72%, Ni:0 to 3% and Co:28 to 48% in atomic ratio is equal to about 24,000 gauss. That is, the saturated magnetic density in the case of the alloy is about twice as large as that in the case of pure cobalt soft magnetic film.

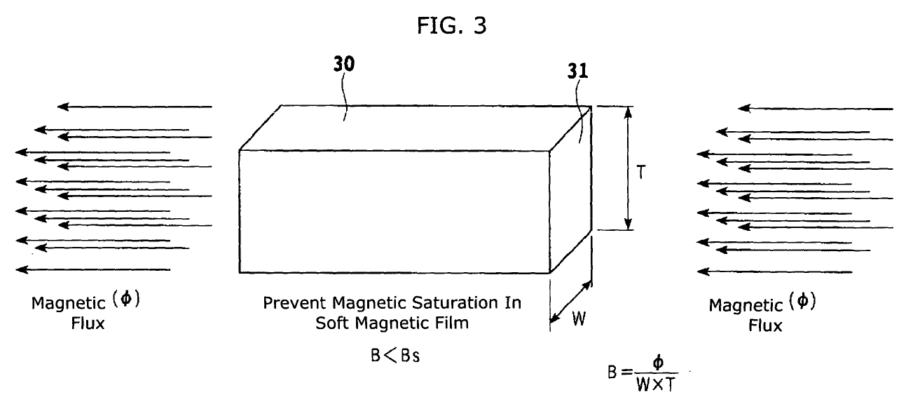

FIG. 3 shows a model used to calculate the magnetic flux passing through the soft magnetic film. In FIG. 3, the magnetic flux density B of the soft magnetic film 30 when the magnetic flux φ of the horizontal magnetic field passes through the soft magnetic film 30 (saturated magnetic flux density: Bs) of W in width, T in thickness and S (W*T) in sectional area can be represented by B=φ/S=φ/(W*T) if it is assumed for the sake of simplicity that all the magnetic flux φ are vertically incident to the surface 31 having the sectional area S of the soft magnetic film 30 and vertically emitted therefrom, and the magnetic flux density in the soft magnetic film 30 is uniform. Accordingly, in the case of the soft magnetic film formed of the alloy of Fe, Ni, and Co having the above composition, the saturated magnetic flux density thereof can be increased to about twice that of the Co film. Therefore, if the magnetic flux incident to the soft magnetic film and the width of the soft magnetic film are fixed, the thickness of the soft magnetic film can be reduced by half.

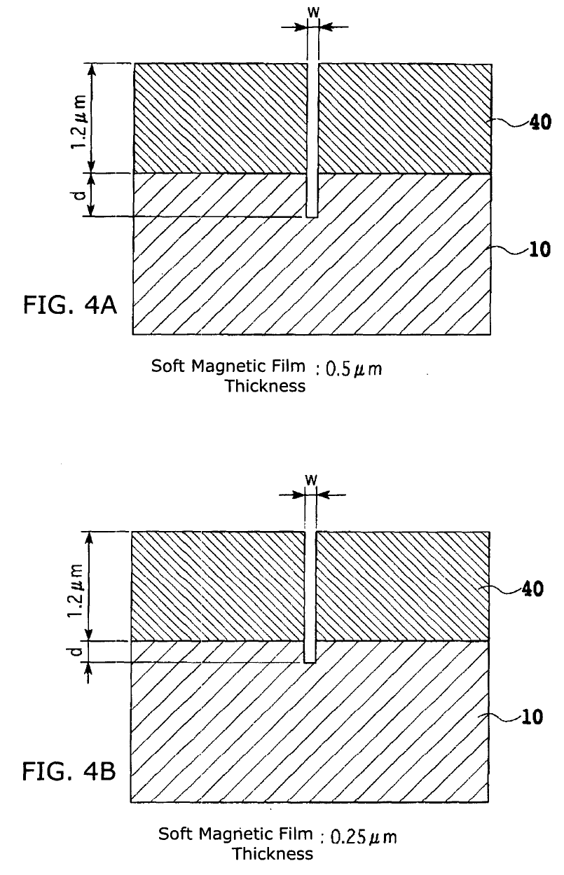

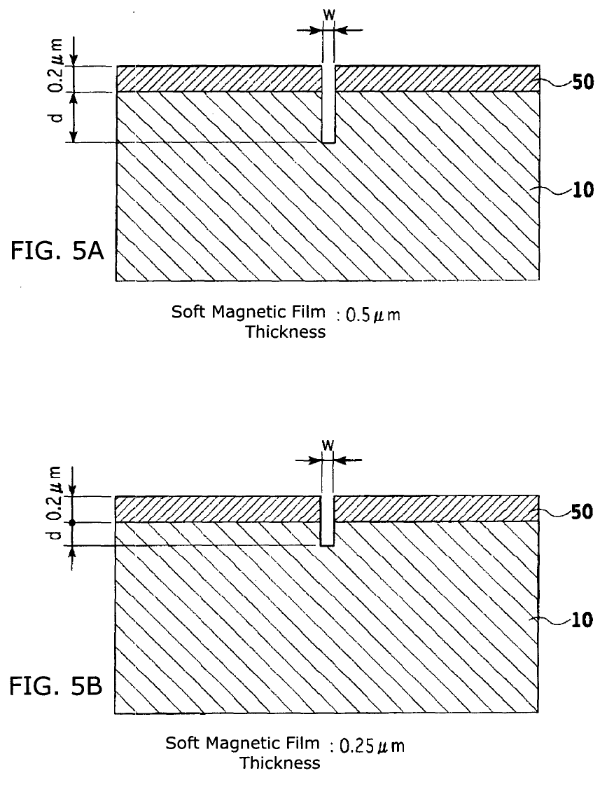

FIGS. 4A and 4B show cross sections of the soft magnetic film embedded into the grooves of w=0.1 μm in groove width and d=0.51 μm and 0.25 μm in depth when the thickness of the soft magnetic film (not shown) is set to 0.5 μm using the Co film (first embodiment) and 0.25 μm using the soft magnetic film formed of the alloy material of Co, Fe, and Ni (second embodiment), and the film thickness of the resist film 40 serving as an etching mask is set to 1.2 μm. As the film thickness of the resist film 40 is large, the ratio in aspect ratio of the grooves between the first and second embodiments is equal to 17.0:14.5, which is not that different from each other. However, if an SiO₂ film resistance to Si etching is used as a mask material in place of the photoresist, the thickness of SiO₂ can be reduced to about 0.2 μm as shown in FIGS. 5A and 5B.

FIGS. 5A and 5B show cross sections of the soft magnetic film embedded into the grooves of w=01 μm in groove width and d=0.5 μm and 0.25 μm in depth when the thickness of the soft magnetic film (not shown) is set to 0.5 μm using the Co film (first embodiment) and 0.25 μm using the soft magnetic film formed of the alloy material of Co, Fe, and Ni (second embodiment), and the SiO₂ film 50 serving as an etching mask is set to 0.2 μm thick. When the mask material is formed of SiO₂, the film thickness can be small. Therefore, the aspect ratio of the grooves between the first and second embodiments is equal to 7:4.5, which is greatly different from each other. The soft magnetic film can be more easily embedded in the grooves in this embodiment.

According to the method of manufacturing the master disc for magnetic transfer of this invention, the film thickness distribution of the soft magnetic film can be suppressed even when the width of the grooves in which the soft magnetic film is embedded is set to sub-micron, so that the dispersion of the data width of the magnetic recording medium after the magnetic transfer can be reduced, and reliability to data read from the magnetic recording medium can be enhanced. Moreover, the permissible magnetic flux density per unit area can be increased, and the thickness of the soft magnetic layer can be reduced.

Given the disclosure of the present invention, one versed in the art would appreciate that there may be other embodiments and modifications within the scope and spirit of the present invention. Accordingly, all modifications and equivalents attainable by one versed in the art from the present disclosure within the scope and spirit of the present invention are to be included as further embodiments of the present invention. The scope of the present invention accordingly is to be defined as set forth in the appended claims.

The disclosure of the priority application, JP 2003-037306, in its entirety, including the drawings, claims, and the specification thereof, is incorporated herein by reference.

What is claimed is:

1. A method of manufacturing a master disc for transferring a magnetic pattern to a magnetic recording medium, comprising the steps of:
providing a substrate;
forming an SiO₂ film on the surface of the substrate;
forming a pattern on the SiO₂ film corresponding to a predetermined magnetic pattern;
etching the substrate using the patterned SiO₂ film as a mask to form grooves corresponding to the predetermined magnetic pattern;
embedding a soft magnetic film in the grooves; and
removing the patterned SiO₂ film.

2. A method according to claim 1, wherein the substrate is a silicon substrate.

3. A method according to claim 2, wherein the soft magnetic film is formed of cobalt or an alloy of iron (Fe) and cobalt (Co) or an alloy of iron, cobalt, and nickel (Ni).

4. A method according to claim 3, wherein the composition of the alloy is set to satisfy an atomic ratio of Fe: 52 to 72%, Co: 28 to 48%, and Ni: 0 to 3%.

5. A method according to claim 1, wherein the pattern forming step includes the steps of forming a photoresist film on the SiO₂ film, patterning the photoresist film corresponding to the predetermined magnetic pattern, developing the photoresist film to form a photoresist mask for etching the SiO₂ film, and etching the Si0₂ to form the pattern of SiO₂ film corresponding to the predetermined magnetic pattern, and further including the step of removing the patterned photoresist film before etching the substrate.

6. A method according to claim 2, wherein the pattern forming step includes the steps of forming a photoresist film on the SiO₂ film, patterning the photoresist film corresponding to the predetermined magnetic pattern, developing the photoresist film to form a photoresist mask for etching the SiO₂ film, and etching the SiO₂ to form the pattern of SiO₂ film corresponding to the predetermined magnetic pattern, and further including the step of removing the patterned photoresist film before etching the substrate.

7. A method according to claim 3, wherein the pattern forming step includes the steps of forming a photoresist film on the SiO₂ film, patterning the photoresist film corresponding to the predetermined magnetic pattern, developing the photoresist film to form a photoresist mask for etching the SiO₂ film, and etching the SiO₂ to form the pattern of SiO₂ film corresponding to the predetermined magnetic pattern, and further including the step of removing the patterned photoresist film before etching the substrate.

8. A method according to claim 4, wherein the pattern forming step includes the steps of forming a photoresist film on the SiO₂ film, patterning the photoresist film corresponding to the predetermined magnetic pattern, developing the photoresist film to form a photoresist mask for etching the SiO₂ film, and etching the SiO₂ to form the pattern of SiO₂ film corresponding to the predetermined magnetic pattern, and further including the step of removing the patterned photoresist film before etching the substrate.

9. A method according to claim 3, wherein the SiO₂ film having a thickness of 0.2 μm is formed on the surface of the substrate by thermal oxidation.

10. A method according to claim 9, wherein the depth of the grooves in the substrate is 0.5 μm.

11. A method according to claim 4, wherein the SiO₂ film having a thickness of 0.2 μm is formed on the surface of the substrate by thermal oxidation.

12. A method according to claim 11, wherein the depth of the grooves in the substrate is 0.25 μm.

13. A master disc formed according to the method of claim 1.

14. A master disc formed according to the method of claim 2

15. A master disc formed according to the method of claim 3.

16. A master disc formed according to the method of claim 4.

17. A master disc formed according to the method of claim 5.

18. A master disc for transferring a magnetic pattern to a magnetic recording medium, comprising:
a silicon substrate having grooves corresponding to a magnetic pattern; and
a magnetic material filling the grooves,
wherein the magnetic material is formed of an alloy of iron (Fe) and cobalt (Co) or an alloy of iron, cobalt, and nickel (Ni).

19. A master disc according to claim 18, wherein the composition of the alloy satisfies an atomic ratio of Fe: 52 to 72%, Co: 28 to 48%, and Ni: 0 to 3%.

20. A master disc according to claim 19, wherein the grooves are 0.25 μm deep.
